(19) United States
(12) Patent Application Publication
(10) Pub. No.: US 2025/0116721 A1
(43) Pub. Date: Apr. 10, 2025

(54) APPARATUS FOR DIAGNOSING STATE OF BATTERY

(71) Applicants: Hyundai Motor Company, Seoul (KR); Kia Corporation, Seoul (KR)

(72) Inventors: Hee Gun Yang, Seongnam-si (KR); Kang Woo Bae, Suwon-si (KR); Sung In Baek, Hwaseong-si (KR); Seong Min Yoon, Suwon-si (KR); Young Soo Lee, Incheon (KR)

(21) Appl. No.: 18/437,388

(22) Filed: Feb. 9, 2024

(30) Foreign Application Priority Data
Oct. 4, 2023 (KR) 10-2023-0131869

(51) Int. Cl. G01R 31/392; G01R 31/396; H01M 10/42; H01M 10/48; H02J 7/00

(52) U.S. Cl. CPC G01R 31/392; G01R 31/396; H01M 10/4285; H01M 10/486; H01M 2010/4271; H02J 7/00712

(57) ABSTRACT

An embodiment apparatus for diagnosing a state of a battery pack includes a voltage sensor configured to measure a voltage of each battery cell of the battery pack, a temperature sensor configured to measure a temperature of each battery cell, and a controller configured to perform cell balancing on each battery cell, discharge the battery pack at a preset current, and diagnose the state of the battery pack based on the temperature and the voltage of each battery cell in response to the voltage of the battery pack reaching a cutoff voltage.

### CROSS-REFERENCE TO RELATED APPLICATIONS

This application claims the benefit of Korean Patent Application No. 10-2023-0131869, filed on Oct. 4, 2023, which application is hereby incorporated herein by reference.

### TECHNICAL FIELD

The present disclosure relates to a technology for diagnosing a state of a battery pack including a plurality of battery cells.

### BACKGROUND

Generally, a battery pack used in an energy storage system (ESS) and an electric vehicle (EV) forms a preset number of groups in which a plurality of battery cells are connected in parallel to each other to increase current capacity, and it also has a structure in which the groups are connected in series to each other in order to output voltage.

In this case, the battery cell includes a positive electrode current collector, a negative electrode current collector, a separator, an active material, an electrolyte, and the like, and it can be repeatedly charged and discharged through electrochemical reactions between components. In order to protect the plurality of battery cells from external shocks such as heat, vibration, and the like, a battery module may be formed by combining the plurality of battery cells into one. In order to systematically manage a plurality of battery modules, a battery pack (i.e., a battery system) may be formed by using the plurality of battery modules, a battery management system (BMS), and a cooling device.

Although a plurality of battery cells constituting a battery pack are high quality battery cells that have passed individual inspection, internal damage may occur in some battery cells due to long-term neglect and welding during installation in the battery pack. As a result, some battery cells that have suffered internal damage during the battery pack initialization process may have a voltage difference compared to most normal battery cells.

Because a conventional technology for diagnosing the state of a battery pack diagnoses the state of the battery pack while ignoring the voltage difference that occurs in some battery cells during the process of initializing the battery pack, that is, without precisely initializing the battery pack, the conventional technology may not detect a defective battery pack with high accuracy.

The matters described in this background section are intended to promote an understanding of the background of embodiments of the disclosure and may include matters that are not already known to those of ordinary skill in the art.

### SUMMARY

Embodiments of the present disclosure can solve problems occurring in the prior art while advantages achieved by the prior art are maintained intact.

An embodiment of the present disclosure provides an apparatus for diagnosing a state of a battery pack and a method thereof that may detect a defective battery pack with high accuracy by performing cell balancing on each battery cell constituting a battery pack, discharging the battery pack at a preset current, and diagnosing the state of the battery pack based on the temperature and voltage of each battery cell when the voltage of the battery pack reaches a cutoff voltage.

Another embodiment of the present disclosure provides an apparatus for diagnosing a state of a battery pack and a method thereof that may detect a defective battery pack with high accuracy by measuring a voltage value of each battery cell constituting the battery pack, determining an average voltage value based on the remaining voltage values excluding the maximum voltage value and the minimum voltage value among voltage values of each battery cell, determining an allowable voltage value range by assigning a tolerance to the average voltage value, and performing cell balancing to enable the voltage of each battery cell to enter the allowable voltage value range.

Still another embodiment of the present disclosure provides an apparatus for diagnosing a state of a battery pack and a method thereof that may detect a defective battery pack with high accuracy by performing cell balancing on each battery cell constituting a battery pack, discharging the battery pack at a preset current, measuring a temperature value of each battery cell when a voltage of the battery pack reaches a cutoff voltage, determining an average temperature value by using remaining temperature values excluding the maximum temperature value and the minimum temperature value among temperature values of each battery cell, and diagnosing the state of the battery pack based on the maximum temperature value, the minimum temperature value, and the average temperature value.

Still another embodiment of the present disclosure provides an apparatus for diagnosing a state of a battery pack and a method thereof that may detect a defective battery pack with high accuracy by performing cell balancing on each battery cell constituting a battery pack, discharging the battery pack at a preset current, measuring a voltage value of each battery cell when a voltage of the battery pack reaches a cutoff voltage, determining an average voltage value by using remaining voltage values excluding the maximum voltage value and the minimum voltage value among voltage values of each battery cell, and diagnosing the state of the battery pack based on the maximum voltage value, the minimum voltage value, and the average voltage value.

The technical problems solvable by embodiments of the present disclosure are not limited to the aforementioned problems, and any other technical problems not mentioned herein will be clearly understood from the following description by those skilled in the art to which the present disclosure pertains. Also, it may be easily understood that the objects and advantages of embodiments of the present disclosure may be realized by the units and combinations thereof recited in the claims.

According to an embodiment of the present disclosure, an apparatus for diagnosing a state of a battery pack includes a voltage sensor that measures a voltage of each battery cell of the battery pack, a temperature sensor that measures a temperature of each battery cell, and a controller that performs cell balancing on each battery cell, discharges the battery pack at a preset current, and diagnoses the state of the battery pack based on the temperature and the voltage of each battery cell in response to the voltage of the battery pack reaching a cutoff voltage.

According to an embodiment, the controller may determine an average voltage value based on remaining voltage values excluding a maximum voltage value and a minimum voltage value among voltage values of each battery cell, determine an allowable voltage value range by assigning a tolerance to the average voltage value, and perform the cell balancing to bring the voltage of each battery cell into the allowable voltage value range.

According to an embodiment, the controller may charge a first battery cell in response to the voltage of the first battery cell being less than a minimum value in the allowable voltage value range and discharge the first battery cell in response to the voltage of the first battery cell exceeding a maximum value in the allowable voltage value range.

According to an embodiment, the controller may determine an average temperature value based on remaining temperature values excluding a maximum temperature value and a minimum temperature value among temperature values of each battery cell and diagnose the state of the battery pack based on the maximum temperature value, the minimum temperature value, and the average temperature value.

According to an embodiment, the controller may determine an allowable temperature value by assigning a tolerance to the average temperature value and diagnose the battery pack as defective based on a difference between the maximum temperature value and the average temperature value exceeding the allowable temperature value.

According to an embodiment, the controller may determine an allowable temperature value by assigning a tolerance to the average temperature value and diagnose the battery pack as defective based on a difference between the average temperature value and the minimum temperature value being less than the allowable temperature value.

According to an embodiment, the controller may determine an average voltage value based on remaining voltage values excluding a maximum voltage value and a minimum voltage value among voltage values of each battery cell and diagnose the state of the battery pack based on the maximum voltage value, the minimum voltage value, and the average voltage value.

According to an embodiment, the controller may determine an allowable voltage value by assigning a tolerance to the average voltage value and diagnose the battery pack as defective based on a difference between the maximum voltage value and the average voltage value exceeding the allowable voltage value.

According to an embodiment, the controller may determine an allowable voltage value by assigning a tolerance to the average voltage value and diagnose the battery pack as defective based on a difference between the average voltage value and the minimum voltage value being less than the allowable voltage value.

According to an embodiment, the controller may determine an average temperature value based on remaining temperature values excluding a maximum temperature value and a minimum temperature value among temperature values of each battery cell, primarily diagnose the state of the battery pack based on the maximum temperature value, the minimum temperature value, and the average temperature value, determine an average voltage value based on remaining voltage values excluding a maximum voltage value and a minimum voltage value among voltage values of each battery cell, and secondarily diagnose the state of the battery pack based on the maximum voltage value, the minimum voltage value, and the average voltage value.

According to another embodiment of the present disclosure, a method of diagnosing a state of a battery pack includes measuring, by a voltage sensor, a voltage of each battery cell of the battery pack, measuring, by a temperature sensor, a temperature of each battery cell, performing, by a controller, cell balancing on each battery cell, discharging, by the controller, the battery pack at a preset current, and diagnosing, by the controller, the state of the battery pack based on the temperature and the voltage of each battery cell in response to the voltage of the battery pack reaching a cutoff voltage.

According to an embodiment, the performing of the cell balancing may comprise determining an average voltage value based on remaining voltage values excluding a maximum voltage value and a minimum voltage value among voltage values of each battery cell, determining an allowable voltage value range by assigning a tolerance to the average voltage value, and bringing the voltage of each battery cell into the allowable voltage value range.

According to an embodiment, the bringing of the voltage of each battery cell into the allowable voltage value range may comprise charging, by the controller, a first battery cell in response to the voltage of the first battery cell being less than a minimum value in the allowable voltage value range and discharging, by the controller, the first battery cell in response to the voltage of the first battery cell exceeding a maximum value in the allowable voltage value range.

According to an embodiment, the diagnosing of the state of the battery pack may comprise determining, by the controller, an average temperature value based on remaining temperature values excluding a maximum temperature value and a minimum temperature value among temperature values of each battery cell and diagnosing, by the controller, the state of the battery pack based on the maximum temperature value, the minimum temperature value, and the average temperature value.

According to an embodiment, the diagnosing of the state of the battery pack based on the maximum temperature value, the minimum temperature value, and the average temperature value may comprise determining, by the controller, an allowable temperature value by assigning a tolerance to the average temperature value and diagnosing, by the controller, the battery pack as defective based on a difference between the maximum temperature value and the average temperature value exceeding the allowable temperature value.

According to an embodiment, the diagnosing the state of the battery pack based on the maximum temperature value, the minimum temperature value, and the average temperature value may comprise determining, by the controller, an allowable temperature value by assigning a tolerance to the average temperature value and diagnosing, by the controller, the battery pack as defective based on a difference between the average temperature value and the minimum temperature value being less than the allowable temperature value.

According to an embodiment, the diagnosing of the state of the battery pack may comprise determining, by the controller, an average voltage value based on remaining voltage values excluding a maximum voltage value and a minimum voltage value among voltage values of each battery cell and diagnosing, by the controller, the state of the battery pack based on the maximum voltage value, the minimum voltage value, and the average voltage value.

According to an embodiment, the diagnosing of the state of the battery pack based on the maximum voltage value, the minimum voltage value, and the average voltage value may comprise determining, by the controller, an allowable voltage value by assigning a tolerance to the average voltage value and diagnosing, by the controller, the battery pack as defective based on a difference between the maximum voltage value and the average voltage value exceeding the allowable voltage value.

According to an embodiment, the diagnosing the state of the battery pack based on the maximum temperature value, the minimum temperature value, and the average temperature value may comprise determining, by the controller, an allowable voltage value by assigning a tolerance to the average voltage value and diagnosing, by the controller, the battery pack as defective based on a difference between the average voltage value and the minimum voltage value being less than the allowable voltage value.

According to an embodiment, the diagnosing the state of the battery pack may comprise determining, by the controller, an average temperature value based on remaining temperature values excluding a maximum temperature value and a minimum temperature value among temperature values of each battery cell, primary diagnosing, by the controller, the state of the battery pack based on the maximum temperature value, the minimum temperature value, and the average temperature value, determining, by the controller, an average voltage value based on remaining voltage values excluding a maximum voltage value and a minimum voltage value among voltage values of each battery cell, and secondary diagnosing, by the controller, the state of the battery pack based on the maximum voltage value, the minimum voltage value, and the average voltage value.

### BRIEF DESCRIPTION OF THE DRAWINGS

The above and other objects, features, and advantages of embodiments of the present disclosure will be more apparent from the following detailed description taken in conjunction with the accompanying drawings, in which:

FIG. 1 is a diagram illustrating an apparatus for diagnosing a state of a battery pack according to an embodiment of the present disclosure;

FIG. 2 is a diagram illustrating the configuration of a sensor device and a charging/discharging device provided in an apparatus for diagnosing a state of a battery pack according to an embodiment of the present disclosure;

FIG. 3 is a diagram illustrating an example of a structure in which a charger/discharger provided in an apparatus for diagnosing a state of a battery pack according to an embodiment of the present disclosure is connected to a battery cell;

FIG. 4 is a diagram illustrating an example of a structure in which a voltage sensor provided in an apparatus for diagnosing a state of a battery pack according to an embodiment of the present disclosure is connected to a battery cell;

FIG. 5 is a diagram illustrating an example of a process of controlling each switch by a controller provided in an apparatus for diagnosing a state of a battery pack according to an embodiment of the present disclosure;

FIG. 6 is a flowchart illustrating a method of diagnosing a state of a battery pack according to an embodiment of the present disclosure; and

FIG. 7 is a block diagram illustrating a computing system for executing a method of diagnosing a state of a battery pack according to each embodiment of the present disclosure.

### DETAILED DESCRIPTION OF ILLUSTRATIVE EMBODIMENTS

Hereinafter, some embodiments of the present disclosure will be described in detail with reference to the exemplary drawings. In adding the reference numerals to the components of each drawing, it should be noted that the identical or equivalent component is designated by the identical numeral even when it is displayed on other drawings. Further, in describing the embodiments of the present disclosure, a detailed description of the related known configuration or function will be omitted when it is determined that it interferes with the understanding of the embodiments of the present disclosure.

In addition, terms such as first, second, A, B, (a), (b), or the like may be used herein when describing components of embodiments of the present disclosure. The terms are provided only to distinguish the elements from other elements, and the essences, sequences, orders, and numbers of the elements are not limited by the terms. In addition, unless defined otherwise, all terms used herein, including technical or scientific terms, have the same meanings as those generally understood by those skilled in the art to which the present disclosure pertains. The terms defined in the generally used dictionaries should be construed as having the meanings that coincide with the meanings of the contexts of the related technologies and should not be construed as ideal or excessively formal meanings unless clearly defined in the specification of the present disclosure.

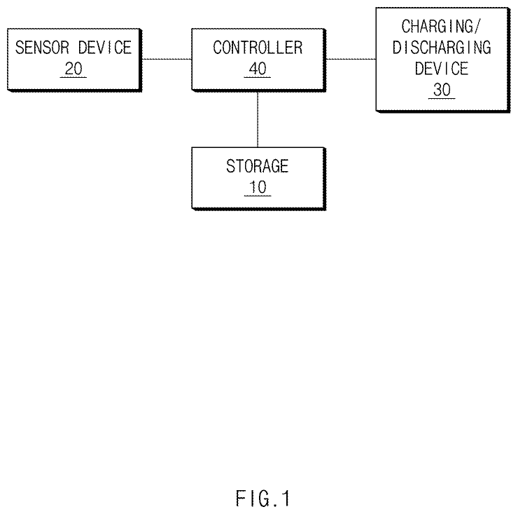

FIG. 1 is a diagram illustrating an apparatus for diagnosing a state of a battery pack according to an embodiment of the present disclosure.

As shown in FIG. 1, an apparatus for diagnosing a state of a battery pack according to an embodiment of the present disclosure may include a storage (i.e., a memory) 10, a sensor device 20, a charging/discharging device 30, and a controller 40. In this case, depending on a scheme of implementing an apparatus for diagnosing a state of a battery cell according to an embodiment of the present disclosure, components may be combined with each other to be implemented as one, or some components may be omitted.

Regarding each component, the storage 10 may store various logic, algorithms, and programs required in the processes of performing cell balancing on each battery cell constituting a battery pack, discharging the battery pack at a preset current, and diagnosing the state of the battery pack based on the temperature and the voltage of each battery cell when the voltage of the battery pack reaches a cutoff voltage.

In addition, the storage 10 may store various logic, algorithms, and programs required in the processes of measuring a voltage value of each battery cell constituting the battery pack, determining an average voltage value based on the remaining voltage values excluding the maximum voltage value and the minimum voltage value among voltage values of each battery cell, determining an allowable voltage value range by assigning a tolerance to the average voltage value, and performing cell balancing to enable the voltage of each battery cell to enter the allowable voltage value range.

In addition, the storage 10 may store various logic, algorithms, and programs required in the processes of performing cell balancing on each battery cell constituting a battery pack, discharging the battery pack at a preset current, measuring a temperature value of each battery cell when a voltage of the battery pack reaches a cutoff voltage, determining an average temperature value by using remaining temperature values excluding the maximum temperature value and the minimum temperature value among temperature values of each battery cell, and diagnosing the state of the battery pack based on the maximum temperature value, the minimum temperature value, and the average temperature value.

In addition, the storage 10 may store various logic, algorithms, and programs required in the processes of performing cell balancing on each battery cell constituting a battery pack, discharging the battery pack at a preset current, measuring a voltage value of each battery cell when a voltage of the battery pack reaches a cutoff voltage, determining an average voltage value by using remaining voltage values excluding the maximum voltage value and the minimum voltage value among voltage values of each battery cell, and diagnosing the state of the battery pack based on the maximum voltage value, the minimum voltage value, and the average voltage value.

The sensor device 20 may include a voltage sensor that measures the voltage of each battery cell constituting the battery pack and a temperature sensor that measures the temperature of each battery cell. The sensor device 20 may further include a current sensor that measures the current of the battery pack.

The charging/discharging device 30 may perform charging and discharging of a battery pack or may perform charging and discharging of each battery cell constituting the battery pack.

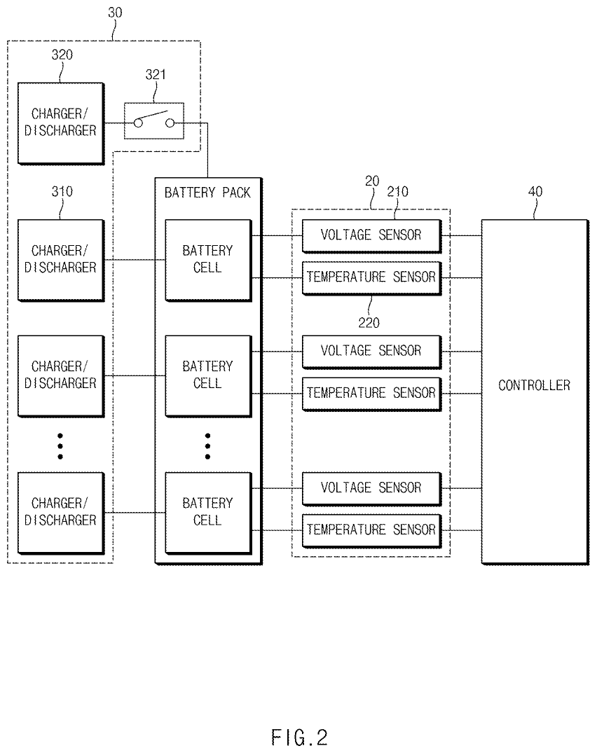

Hereinafter, the configuration of the sensor device 20 and the charging/discharging device 30 will be described in detail with reference to FIGS. 2 to 4.

FIG. 2 is a diagram illustrating the configuration of a sensor device and a charging/discharging device provided in an apparatus for diagnosing a state of a battery pack according to an embodiment of the present disclosure.

As shown in FIG. 2, the sensor device 20 may include a pair of a voltage sensor 210 and a temperature sensor 220 corresponding to each battery cell. Accordingly, the sensor device 20 may measure the voltage and the temperature of each battery cell.

In addition, the charging/discharging device 30 may include a charger/discharger 310 corresponding to each battery cell and a charger/discharger 320 corresponding to a battery pack. In this case, the charger/discharger 310 may perform a function of charging or discharging each battery cell during cell balancing, and the charger/discharger 320 may perform a function of charging or discharging the battery pack during diagnosis of the battery pack. In this case, a main switch 321 controlled by the controller 40 may be located between the charger/discharger 320 and the battery pack.

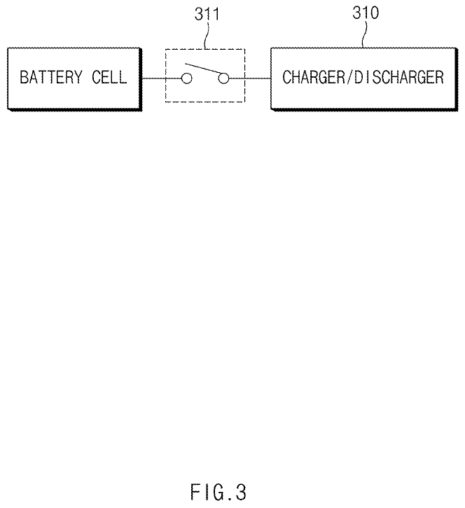

FIG. 3 is a diagram illustrating an example of a structure in which a charger/discharger provided in an apparatus for diagnosing a state of a battery pack according to an embodiment of the present disclosure is connected to a battery cell.

As shown in FIG. 3, the charger/discharger 310 may include a switch 311 which is controlled by the controller 40 and provided between the charger/discharger 310 and the battery cell. The controller 40 may turn on the switch 311 during cell balancing.

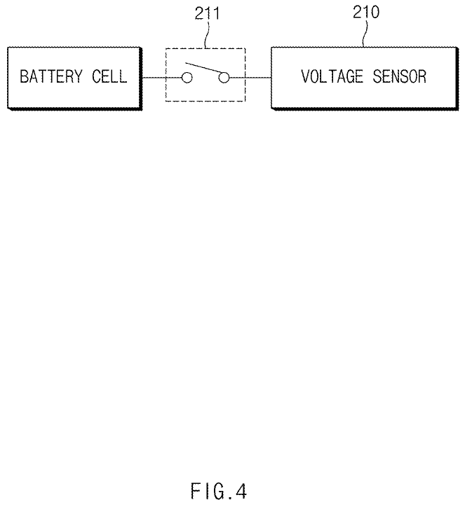

FIG. 4 is a diagram illustrating an example of a structure in which a voltage sensor provided in an apparatus for diagnosing a state of a battery pack according to an embodiment of the present disclosure is connected to a battery cell.

As shown in FIG. 4, a voltage sensor 210 may include a switch 211 which is controlled by the controller 40 and provided between the voltage sensor 210 and the battery cell. The controller 40 may turn on the switch 211 when the battery pack is charged, the battery pack is discharged, or an open circuit voltage (OCV) of the battery cell is measured.

The controller 40 may perform overall control such that each component performs its function. The controller 40 may be implemented in the form of hardware or software, or it may be implemented in a combination of hardware and software. Preferably, the controller 40 may be implemented as a microprocessor, but it is not limited thereto.

The controller 40 may perform cell balancing on each battery cell constituting the battery pack by using the charger/discharger 310 of the charging/discharging device 30, discharge the battery pack at a preset current by using the charger/discharger 320 of the charging/discharging device 30, and diagnose the state of the battery pack based on the temperature and the voltage of each battery cell when the voltage of the battery pack reaches a cutoff voltage. In this case, the cutoff voltage, which is a voltage value at which the battery pack is considered to be fully discharged, may be set according to the designer's intention.

In this case, the controller 40 may measure a voltage value of each battery cell constituting the battery pack, determine an average voltage value based on the remaining voltage values excluding the maximum voltage value and the minimum voltage value among voltage values of each battery cell, determine an allowable voltage value range by assigning a tolerance to the average voltage value, and perform cell balancing to enable the voltage of each battery cell to enter the allowable voltage value range.

For example, when the voltage of the first battery cell exceeds the reference value (e.g., 5%) compared to the average voltage value, the controller 40 may discharge the first battery cell. As another example, when the voltage of the second battery cell is less than the reference value (e.g., 5%) compared to the average voltage value, the controller 40 may charge the second battery cell.

In addition, the controller 40 may measure the temperature value of each battery cell, determine an average temperature value by using remaining temperature values excluding the maximum temperature value and the minimum temperature value among temperature values of each battery cell, and diagnose the state of the battery pack based on the maximum temperature value, the minimum temperature value and the average temperature value.

In this case, the controller 40 may determine an allowable temperature value by assigning a tolerance (e.g., 5%) to the average temperature value, and diagnose the battery pack as defective when a difference between the maximum temperature value and the average temperature value exceeds the allowable temperature value. In addition, the controller 40 may diagnose the battery pack as defective when the difference between the average temperature value and the minimum temperature value is less than the allowable temperature value.

In addition, the controller 40 may measure the voltage value of each battery cell, determine the average voltage value based on remaining voltage values excluding the maximum voltage value and the minimum voltage value among voltage values of each battery cell, and diagnose the state of the battery pack based on the maximum voltage value, the minimum voltage value, and the average voltage value.

In this case, the controller 40 may determine an allowable voltage value by assigning a tolerance (e.g., 5%) to the average temperature value and diagnose the battery pack as defective when the difference between the maximum voltage value and the average voltage value exceeds the allowable voltage value. In addition, the controller 40 may diagnose the battery pack as defective when the difference between the average voltage value and the minimum voltage value is less than the allowable voltage value.

In addition, the controller 40 may set the temperature of a chamber that maintains constant temperature and constant humidity to room temperature (e.g., 25° C.) and perform the process of diagnosing a state of a battery pack described above when the temperature of a battery pack to be diagnosed is room temperature, but the embodiment is not necessarily limited thereto.

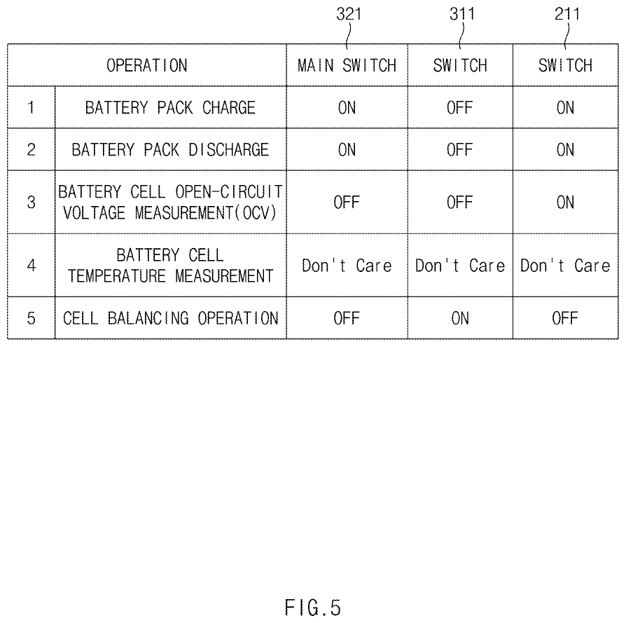

Meanwhile, as shown in FIG. 5, the controller 40 may control the state of each of the switches 321, 311, and 211 in the process of diagnosing a state of a battery pack.

FIG. 5 is a diagram illustrating an example of a process of controlling each switch by a controller provided in an apparatus for diagnosing a state of a battery pack according to an embodiment of the present disclosure.

As shown in FIG. 5, when charging the battery pack, the controller 40 controls the main switch 321 to be in the ON state, the switch 311 to be in the OFF state, and the switch 211 to be in the ON state. When the battery pack is discharged, the controller 40 controls the main switch 321 to be in the ON state, the switch 311 to be in the OFF state, and the switch 211 to be in the ON state. When measuring the open-circuit voltage of a battery cell, the controller 40 controls the main switch 321 to be in the OFF state, the switch 311 to be in the OFF state, and the switch 211 to be in the ON state. When measuring the temperature of a battery cell, the controller 40 is not involved in the state of the main switch, the state of the switch 311, and the state of the switch 211. During cell balancing, the controller 40 controls the main switch 321 to be in the OFF state, the switch 311 to be in the ON state, and the switch 211 to be in the OFF state.

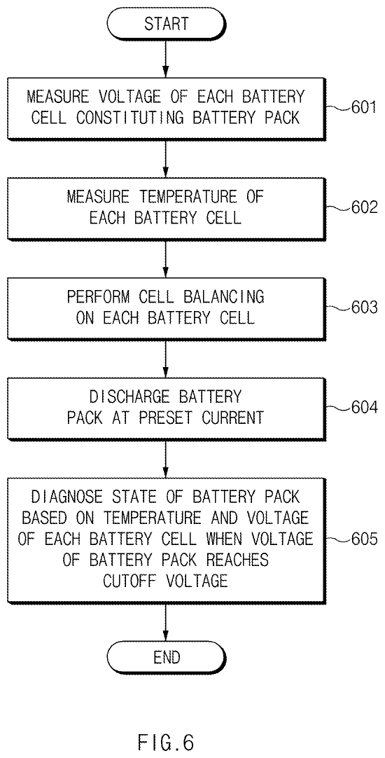

FIG. 6 is a flowchart illustrating a method of diagnosing a state of a battery pack according to an embodiment of the present disclosure.

First, the sensor device 20 measures the temperature and the voltage of each battery cell constituting the battery pack. That is, the voltage sensor 210 of the sensor device 20 measures the voltage of each battery cell in 601, and a temperature sensor 220 of the sensor device 20 measures the temperature of each battery cell in 602.

Then, the controller 40 performs cell balancing on each battery cell in 603.

Then, the controller 40 discharges the battery pack at a preset current in 604.

When the voltage of the battery pack reaches the cutoff voltage, the controller 40 diagnoses the state of the battery pack based on the temperature and the voltage of each battery cell in 605.

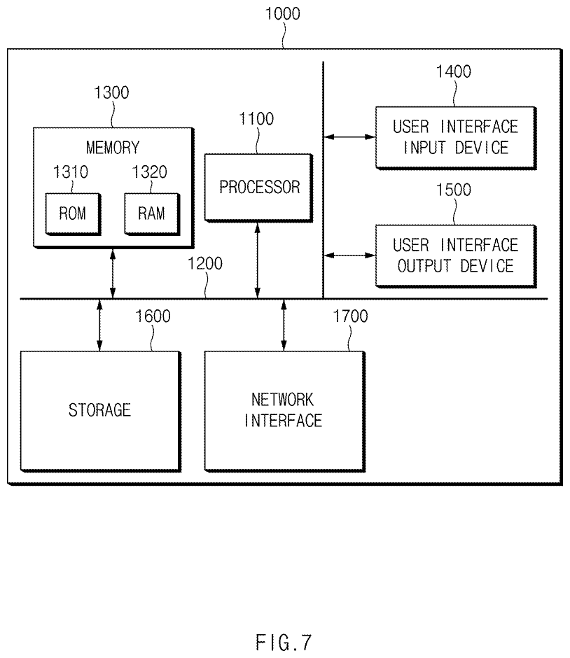

FIG. 7 is a block diagram illustrating a computing system for executing a method of diagnosing a state of a battery pack according to each embodiment of the present disclosure.

Referring to FIG. 7, a method of diagnosing a state of a battery pack according to an embodiment of the present disclosure described above may be implemented through a computing system 1000. The computing system 1000 may include at least one processor 1100, a memory 1300, a user interface input device 1400, a user interface output device 1500, a storage (i.e., a memory) 1600, and a network interface 1700 connected through a system bus 1200.

The processor 1100 may be a central processing device (CPU) or a semiconductor device that processes instructions stored in the memory 1300 and/or the storage 1600. The memory 1300 and the storage 1600 may include various types of volatile or non-volatile storage media. For example, the memory 1300 may include a ROM (Read Only Memory) 1310 and a RAM (Random Access Memory) 1320.

Accordingly, the processes of the method or algorithm described in relation to the embodiments of the present disclosure may be implemented directly by hardware executed by the processor 1100, a software module, or a combination thereof. The software module may reside in a storage medium (that is, the memory 1300 and/or the storage 1600), such as a RAM, a flash memory, a ROM, an EPROM, an EEPROM, a register, a hard disk, a solid state drive (SSD), a detachable disk, or a CD-ROM. The exemplary storage medium is coupled to the processor 1100, and the processor 1100 may read information from the storage medium and may write information in the storage medium. In another method, the storage medium may be integrated with the processor 1100. The processor 1100 and the storage medium may reside in an application specific integrated circuit (ASIC). The ASIC may reside in a user terminal. In another method, the processor 1100 and the storage medium may reside in the user terminal as an individual component.

According to the embodiments of the present disclosure, it is possible to detect a defective battery pack with high accuracy by performing cell balancing on each battery cell constituting a battery pack, discharging the battery pack at a preset current, and diagnosing the state of the battery pack based on the temperature and the voltage of each battery cell when the voltage of the battery pack reaches a cutoff voltage.

Although exemplary embodiments of the present disclosure have been described for illustrative purposes, those skilled in the art will appreciate that various modifications, additions, and substitutions are possible, without departing from the scope and spirit of the disclosure. Therefore, the exemplary embodiments disclosed in the present disclosure are provided for the sake of descriptions, not limiting the technical concepts of the present disclosure, and it should be understood that such exemplary embodiments are not intended to limit the scope of the technical concepts of the present disclosure. The protection scope of the present disclosure should be understood by the claims below, and all the technical concepts within the equivalent scopes should be interpreted to be within the scope of the right of the present disclosure.

What is claimed is:

1. An apparatus for diagnosing a state of a battery pack, the apparatus comprising:
a voltage sensor configured to measure a voltage of each battery cell of the battery pack;
a temperature sensor configured to measure a temperature of each battery cell; and
a controller configured to perform cell balancing on each battery cell, discharge the battery pack at a preset current, and diagnose the state of the battery pack based on the temperature and the voltage of each battery cell in response to the voltage of the battery pack reaching a cutoff voltage.

2. The apparatus of claim 1, wherein the controller is configured to determine an average voltage value based on remaining voltage values excluding a maximum voltage value and a minimum voltage value among voltage values of each battery cell, to determine an allowable voltage value range by assigning a tolerance to the average voltage value, and to perform the cell balancing to bring the voltage of each battery cell into the allowable voltage value range.

3. The apparatus of claim 2, wherein the controller is configured to charge a first battery cell in response to the voltage of the first battery cell being less than a minimum value in the allowable voltage value range and to discharge the first battery cell in response to the voltage of the first battery cell exceeding a maximum value in the allowable voltage value range.

4. The apparatus of claim 1, wherein the controller is configured to determine an average temperature value based on remaining temperature values excluding a maximum temperature value and a minimum temperature value among temperature values of each battery cell and to diagnose the state of the battery pack based on the maximum temperature value, the minimum temperature value, and the average temperature value.

5. The apparatus of claim 4, wherein the controller is configured to determine an allowable temperature value by assigning a tolerance to the average temperature value and to diagnose the battery pack as defective based on a difference between the maximum temperature value and the average temperature value exceeding the allowable temperature value.

6. The apparatus of claim 4, wherein the controller is configured to determine an allowable temperature value by assigning a tolerance to the average temperature value and to diagnose the battery pack as defective based on a difference between the average temperature value and the minimum temperature value being less than the allowable temperature value.

7. The apparatus of claim 1, wherein the controller is configured to determine an average voltage value based on remaining voltage values excluding a maximum voltage value and a minimum voltage value among voltage values of each battery cell and to diagnose the state of the battery pack based on the maximum voltage value, the minimum voltage value, and the average voltage value.

8. The apparatus of claim 7, wherein the controller is configured to determine an allowable voltage value by assigning a tolerance to the average voltage value and to diagnose the battery pack as defective based on a difference between the maximum voltage value and the average voltage value exceeding the allowable voltage value.

9. The apparatus of claim 7, wherein the controller is configured to determine an allowable voltage value by assigning a tolerance to the average voltage value and to diagnose the battery pack as defective based on a difference between the average voltage value and the minimum voltage value being less than the allowable voltage value.

10. The apparatus of claim 1, wherein the controller is configured to determine an average temperature value based on remaining temperature values excluding a maximum temperature value and a minimum temperature value among temperature values of each battery cell, to primarily diagnose the state of the battery pack based on the maximum temperature value, the minimum temperature value, and the average temperature value, to determine an average voltage value based on remaining voltage values excluding a maximum voltage value and a minimum voltage value among voltage values of each battery cell, and to secondarily diagnose the state of the battery pack based on the maximum voltage value, the minimum voltage value, and the average voltage value.

11. A method of diagnosing a state of a battery pack, the method comprising:
measuring a voltage of each battery cell of the battery pack;
measuring a temperature of each battery cell;
performing cell balancing on each battery cell;
discharging the battery pack at a preset current; and
diagnosing the state of the battery pack based on the temperature and the voltage of each battery cell in response to the voltage of the battery pack reaching a cutoff voltage.

12. The method of claim 11, wherein performing the cell balancing comprises:
determining an average voltage value based on remaining voltage values excluding a maximum voltage value and a minimum voltage value among voltage values of each battery cell;
determining an allowable voltage value range by assigning a tolerance to the average voltage value; and
bringing the voltage of each battery cell into the allowable voltage value range.

13. The method of claim 12, wherein bringing the voltage of each battery cell into the allowable voltage value range comprises:
charging a first battery cell in response to the voltage of the first battery cell being less than a minimum value in the allowable voltage value range; and
discharging the first battery cell in response to the voltage of the first battery cell exceeding a maximum value in the allowable voltage value range.

14. The method of claim 11, wherein diagnosing the state of the battery pack comprises:
determining an average temperature value based on remaining temperature values excluding a maximum temperature value and a minimum temperature value among temperature values of each battery cell; and
diagnosing the state of the battery pack based on the maximum temperature value, the minimum temperature value, and the average temperature value.

15. The method of claim 14, wherein diagnosing the state of the battery pack based on the maximum temperature value, the minimum temperature value, and the average temperature value comprises:
determining an allowable temperature value by assigning a tolerance to the average temperature value; and
diagnosing the battery pack as defective based on a difference between the maximum temperature value and the average temperature value exceeding the allowable temperature value.

16. The method of claim 14, wherein diagnosing the state of the battery pack based on the maximum temperature value, the minimum temperature value, and the average temperature value comprises:
determining an allowable temperature value by assigning a tolerance to the average temperature value; and
diagnosing the battery pack as defective based on a difference between the average temperature value and the minimum temperature value being less than the allowable temperature value.

17. The method of claim 11, wherein diagnosing the state of the battery pack comprises:
determining an average voltage value based on remaining voltage values excluding a maximum voltage value and a minimum voltage value among voltage values of each battery cell; and
diagnosing the state of the battery pack based on the maximum voltage value, the minimum voltage value, and the average voltage value.

18. The method of claim 17, wherein diagnosing the state of the battery pack based on the maximum voltage value, the minimum voltage value, and the average voltage value comprises:
determining an allowable voltage value by assigning a tolerance to the average voltage value; and
diagnosing the battery pack as defective based on a difference between the maximum voltage value and the average voltage value exceeding the allowable voltage value.

19. The method of claim 17, wherein diagnosing the state of the battery pack based on the maximum voltage value, the minimum voltage value, and the average voltage value comprises:
determining an allowable voltage value by assigning a tolerance to the average voltage value; and
diagnosing the battery pack as defective based on a difference between the average voltage value and the minimum voltage value being less than the allowable voltage value.

20. The method of claim 11, wherein diagnosing the state of the battery pack comprises:
determining an average temperature value based on remaining temperature values excluding a maximum temperature value and a minimum temperature value among temperature values of each battery cell;
primary diagnosing the state of the battery pack based on the maximum temperature value, the minimum temperature value, and the average temperature value;
determining an average voltage value based on remaining voltage values excluding a maximum voltage value and a minimum voltage value among voltage values of each battery cell; and
secondary diagnosing the state of the battery pack based on the maximum voltage value, the minimum voltage value, and the average voltage value.
